(19) United States
(12) Patent Application Publication
(10) Pub. No.: US 2020/0258902 A1
(43) Pub. Date: Aug. 13, 2020

(54) 3-DIMENSIONAL JUNCTION SEMICONDUCTOR MEMORY DEVICE AND FABRICATION METHOD THEREOF

(71) Applicant: SiEn (QingDao) Integrated Circuits Co., Ltd, Shandong (CN)

(72) Inventors: Deyuan Xiao, Shandong (CN); Richard R. Chang, Shandong (CN)

(21) Appl. No.: 16/715,143

(22) Filed: Dec. 16, 2019

(30) Foreign Application Priority Data
Dec. 21, 2018 (CN) 201811571907.8

(51) Int. Cl. H01L 27/11582

(52) U.S. Cl. CPC H01L 27/11582; H01L 21/2255

(57) ABSTRACT

This invention provides a three-dimensional (3D) junction semiconductor memory device and fabrication method thereof. The 3D junction semiconductor memory device comprises a plurality of vertical channel structures and a plurality of gate layers staked up in a vertical direction. The pluralities of vertical channel structures comprise multiple alternatively stacked source/drain material layers and channel material layers in a vertical direction, and the source/drain material layers and the channel material layers are doped with different doping types so as to constitute a plurality of junction transistors connected in series vertically, such that not only a smaller component size can be achieved, but also more flexible storage unit operation can be achieved. The fabrication method of 3D junction semiconductor memory device is capably of subtly forming multiple alternatively stacked source/drain material layers and the channel material layers, so as to realize the 3D junction semiconductor memory device which is difficult to be obtained by ion implantation technology.

### CROSS-REFERENCE TO RELATED APPLICATIONS

This application claims priority to P.R.C. Patent Application No. 201811571907.8 titled “3-Dimensional junction semiconductor memory device and fabrication method thereof,” filed on Dec. 21, 2018, with the State Intellectual Property Office of the People's Republic of China (SIPO).

### TECHNICAL FIELD

The present disclosure relates to the design and manufacture of integrated circuits, and particularly, to a three-dimensional junction semiconductor memory device and a fabrication method thereof.

### BACKGROUND

A demand for low-cost semiconductor components with high performance continues to push the integration density. In turn, increased integration density places higher demands on semiconductor manufacturing processes. The integration density of two-dimensional (2D) or planar semiconductor component is partially determined by occupied area of various component that make up the integrated circuit, such as memory unit. The occupied area of various component is greatly determined by the dimensional parameters used to define the individual components and their interconnected patterning techniques, such as width, length, spacing, narrowness, and adjacent separation. In recent years, more and more “fine” patterns requires the development and use of very expensive pattern forming equipment. Therefore, the significant improvement in the integration density of contemporary semiconductor components has paid a considerable price, but designers continue to run up against the practical boundaries of fine pattern development and fabrication.

Due to the aforementioned and many related manufacturing challenges, the recent increased integration density requires the development of multilayer or so-called three-dimensional (3D) semiconductor components. For example, a single fabrication layer conventionally associated with a memory unit array of a 2D semiconductor memory device is being replaced by a multi-fabricated layer or a 3D arrangement of memory unit.

### SUMMARY

In light of the abovementioned problems, an object of the present disclosure is to provide a three-dimensional (3D) junction semiconductor memory device and a fabrication method thereof, which can solve the problem of the integration density of the semiconductor memory device in the prior art.

An objective of the present invention is to provide a fabrication method of 3D junction semiconductor memory device, which comprises the following steps:

providing a substrate;

forming a plurality of vertical channel structures extended upward on the substrate, wherein each one of the pluralities of vertical channel structures comprises multiple alternatively stacked source/drain material layers and channel material layers in a vertical direction, an uppermost layer of the vertical channel structures is one of the source/drain material layers, and the source/drain material layers and the channel material layers are doped with different doping types; and

forming a plurality of gate layers staked up in a vertical direction, wherein each one of the pluralities of gate layers is connected to one of the channel material layers, and the two adjacent gate layers are isolated by one of insulation layers.

In accordance with some embodiments, the step of forming a plurality of vertical channel structures comprises:

forming a composite stack structure on the substrate, wherein the composite stack structure comprises multiple alternatively stacked insulation layers and phosphorus silicon glass sacrificial layers, wherein an uppermost layer of the composite stack structure is one of the insulation layers;

forming a channel hole in the composite stack structure, wherein the channel hole opens from the upper surface of the composite stack structure and extends down to a surface of the substrate;

forming a p-type material layer in the channel hole; and

performing a heating treatment to convert a portion of the p-type material layer contacting the phosphorus silicon glass sacrificial layers into n-type doped channel material layers, such that the p-type material layers above and below the channel material layers respectively compose the source/drain material layers.

In accordance with some embodiments, the channel hole is not filled up with the p-type material layer, the p-type material layer constitutes a hollow structure in the channel hole, and the fabrication method further comprises a step of filling the space remaining in the channel hole with an insulated material.

In accordance with some embodiments, the channel hole is filled up with the p-type material layer, and the p-type material layer constitutes a solid column structure in the channel hole.

In accordance with some embodiments, the method further comprises a step of etching the composite stack structure to form a stair-stepped structure on at least one side of the composite stack structure.

In accordance with some embodiments, a stair surface of the stair-stepped structure exposes a partial surface of the insulation layers.

In accordance with some embodiments, the stair-stepped structure is obtained by a step of etching the pluralities of insulation layers and the pluralities of phosphorus silicon glass sacrificial layers sequentially by using a sequentially decreasing or increasing mask.

In accordance with some embodiments, the method further comprises a step of forming a word line cut in the composite stack structure, wherein the word line cut opens from the upper surface of the composite stack structure and extends down to a surface of the substrate, and the word line cut divides the pluralities of vertical channel structures in groups.

In accordance with some embodiments, the method further comprises a step of replacing the phosphorus silicon glass sacrificial layers with conductive layers to form the gate layers.

In accordance with some embodiments, the method further comprises a step of forming a data storage layer, wherein the data storage layer is disposed between the pluralities of channel material layers and the pluralities of gate layers.

In accordance with some embodiments, the data storage layer is disposed between the pluralities of insulation layers and the pluralities of gate layers.

In accordance with some embodiments, the data storage layer comprises a tunneling dielectric layer, a charge trap layer and a high-K dielectric layer, the tunneling dielectric layer is connected to the pluralities of channel material layers, the high-K dielectric layer is connected to the pluralities of gate layers, the charge trap layer is disposed between the tunneling dielectric layer and the high-K dielectric layer, and dielectric constant K of the high-K dielectric layer is greater than 4.

In accordance with some embodiments, the method further comprises a step of forming a bit line contact and a bit line, the bit line contact is connected to an uppermost layer of the source/drain material layers, and the bit line is connected above the bit line contact.

In accordance with some embodiments, an uppermost layer of the gate layers is connected to a secondary uppermost layer of the gate layers by a conductive connector.

In accordance with some embodiments, a lowermost layer of the gate layers is connected to a secondary lowermost layer of the gate layers by a conductive connector.

Another objective of the present invention is to provide a 3D junction semiconductor memory device. The device comprises:

a substrate;

a plurality of vertical channel structures, extended upward on the substrate, wherein each one of the pluralities of vertical channel structures comprises multiple alternatively stacked source/drain material layers and channel material layers in a vertical direction, an uppermost layer of the vertical channel structures is one of the source/drain material layers, and the source/drain material layers and the channel material layers are doped with different doping types; and

a plurality of gate layers, staked up in a vertical direction, wherein each one of the pluralities of gate layers is connected to one of the channel material layers, and the two adjacent gate layers are isolated by one of insulation layers.

In accordance with some embodiments, the source/drain material layers and the channel material layers constitute a hollow structure, and the hollow structure is filled with an insulated material.

In accordance with some embodiments, the source/drain material layers and the channel material layers constitute a solid column structure.

In accordance with some embodiments, a stair-stepped structure is formed on at least one side of the pluralities of gate layers.

In accordance with some embodiments, the device further comprises a word line cut, wherein the word line cut tunnels the pluralities of gate layers and the insulation layers, and the word line cut divides the pluralities of vertical channel structures in groups.

In accordance with some embodiments, the device further comprises a data storage layer, wherein the data storage layer is disposed between the pluralities of channel material layers and the pluralities of gate layers.

In accordance with some embodiments, the data storage layer is disposed between the pluralities insulation layers and the pluralities of gate layers.

In accordance with some embodiments, the device further comprises a bit line contact and a bit line, wherein the bit line contact is connected to an uppermost layer of the source/drain material layers, and the bit line is connected above the bit line contact.

As described above, the 3D junction semiconductor memory device and the fabrication method thereof have the following beneficial effects: the present invention comprises a plurality of vertical channel structures and a plurality of gate layers staked up in a vertical direction. The pluralities of vertical channel structures comprise multiple alternatively stacked source/drain material layers and channel material layers in a vertical direction, and the source/drain material layers and the channel material layers are doped with different doping types so as to constitute a plurality of junction transistors connected in series vertically, such that not only a smaller component size can be achieved, but also more flexible storage unit operation can be achieved. The fabrication method of 3D junction semiconductor memory device is capably of subtly forming multiple alternatively stacked source/drain material layers and the channel material layers, so as to realize the 3D junction semiconductor memory device which is difficult to be obtained by ion implantation technology.

### BRIEF DESCRIPTION OF THE DRAWINGS

Exemplary embodiments will be more readily understood from the following detailed description when read in conjunction with the appended drawings, in which:

FIG. 1 depicts a flow chart of a fabrication method of a three-dimensional (3D) junction semiconductor memory device according to some embodiments of the present disclosure;

FIG. 2 depicts a cross-sectional diagram of forming a composite stack structure on a substrate in the fabrication method of the 3D junction semiconductor memory device according to some embodiments of the present disclosure;

FIG. 3 depicts a cross-sectional diagram of forming a channel hole in the composite stack structure in the fabrication method of the 3D junction semiconductor memory device according to some embodiments of the present disclosure;

FIG. 4 depicts a cross-sectional diagram of forming a p-type material layer in the channel hole in the fabrication method of the 3D junction semiconductor memory device according to some embodiments of the present disclosure;

FIG. 5 depicts a cross-sectional diagram of filling the space remaining in the channel hole with an insulated material in the channel hole in the fabrication method of the 3D junction semiconductor memory device according to some embodiments of the present disclosure;

FIG. 6 depicts a cross-sectional diagram of converting a portion of the p-type material layer contacting the phosphorus silicon glass sacrificial layers into n-type doped channel material layers in the fabrication method of the 3D junction semiconductor memory device according to some embodiments of the present disclosure;

FIG. 7 depicts a plant layout diagram of a channel hole, a word line cut, and a stair-stepped structure according to some embodiments of the present disclosure;

FIG. 8 depicts a cross-sectional diagram of forming a stair-stepped structure on at least one side of the composite stack structure in the fabrication method of the 3D junction semiconductor memory device according to some embodiments of the present disclosure;

FIG. 9 depicts a cross-sectional diagram of forming a word line cut in the composite stack structure in the fabrication method of the 3D junction semiconductor memory device according to some embodiments of the present disclosure;

FIG. 10 depicts a cross-sectional diagram of removing the phosphorus silicon glass sacrificial layers in the fabrication method of the 3D junction semiconductor memory device according to some embodiments of the present disclosure;

FIG. 11 depicts a cross-sectional diagram of forming a data storage layer in the fabrication method of the 3D junction semiconductor memory device according to some embodiments of the present disclosure;

FIG. 12 depicts a cross-sectional diagram of replacing the phosphorus silicon glass sacrificial layers with conductive layers in the fabrication method of the 3D junction semiconductor memory device according to some embodiments of the present disclosure;

FIG. 13 depicts a cross-sectional diagram of removing the conductive layer in the cut in the fabrication method of the 3D junction semiconductor memory device according to some embodiments of the present disclosure; and

FIG. 14 depicts a cross-sectional diagram of forming a bit line contact and a bit lime in the fabrication method of the 3D junction semiconductor memory device according to some embodiments of the present disclosure.

### DETAILED DESCRIPTION

The embodiments of the present invention are described below by way of specific examples, and those skilled in the art can readily understand other advantages and effects of the present invention from the disclosure of the present disclosure. The present invention may be embodied or applied in various other specific embodiments, and various modifications and changes can be made without departing from the spirit and scope of the invention.

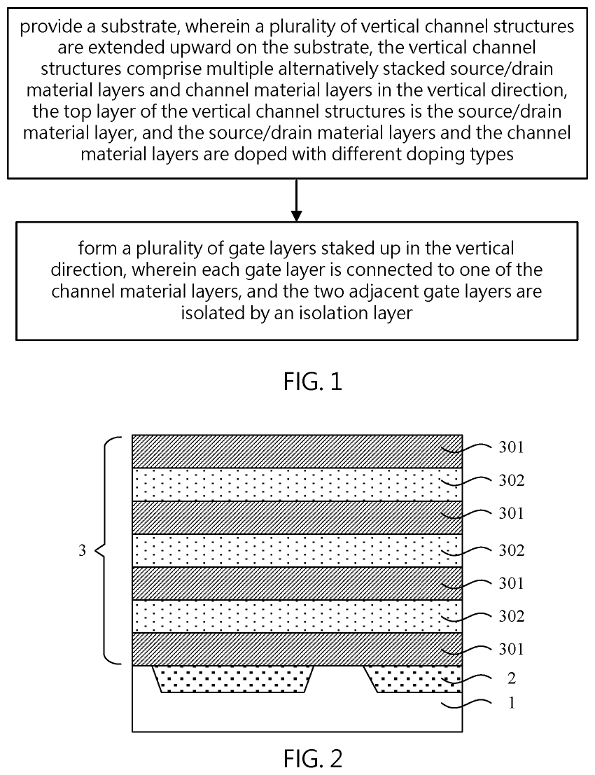

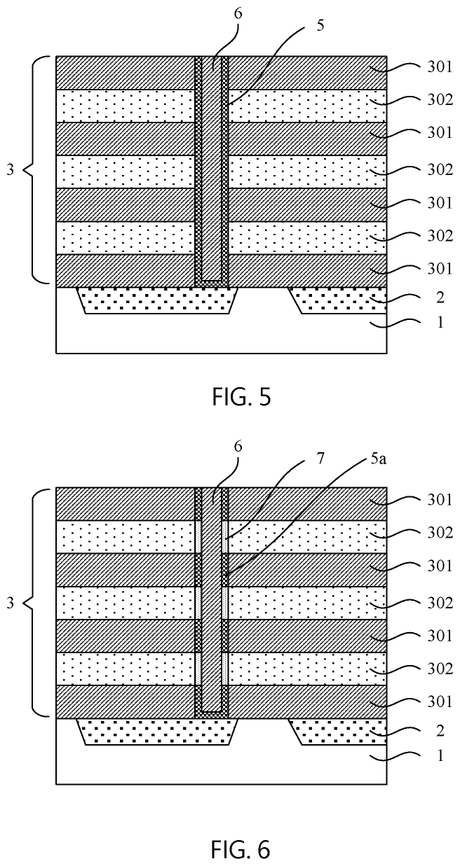

Please refer to FIGS. 1 through 14. It should be noted that the illustrations provided in this embodiment merely illustrate the basic concept of the present invention in a schematic manner, and only the components related to the present invention are shown in the drawings, instead of the number and shape of components in actual implementation. Dimensional drawing, the actual type of implementation of each component type, number and proportion can be a random change, and its component layout can be more complicated.

### First Embodiment

Please refer to FIG. 1, which depicts a flow chart of a fabrication method of a three-dimensional (3D) junction semiconductor memory device according to some embodiments of the present disclosure, and the method comprises steps of:

Please refer to FIGS. 2 through 6, a substrate 1 is provided, a plurality of vertical channel structures may be formed and extended upward on the substrate 1, in which each one of the pluralities of vertical channel structures comprises multiple alternatively stacked source/drain material layers 5a and channel material layers 7 in a vertical direction, an uppermost layer of the vertical channel structures is one of the source/drain material layers 5a, and the source/drain material layers 5a and the channel material layers 7 are doped with different doping types.

For example, the step of forming a plurality of vertical channel structures comprises:

A composite stack structure 3 is formed on the substrate 1, in which the composite stack structure 3 comprises multiple alternatively stacked insulation layers 301 and phosphorus silicon glass sacrificial layers 302, and an uppermost layer of the composite stack structure 3 is one of the insulation layers 301. The material of the insulation layer 301 may comprise silicon dioxide.

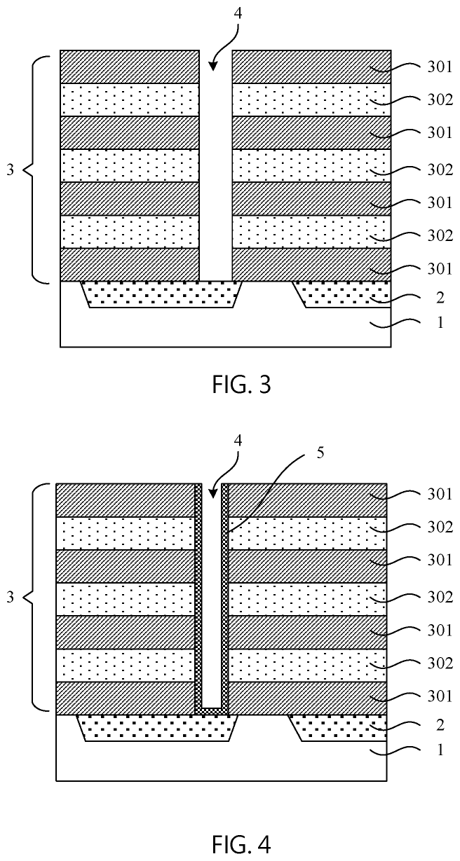

As sown in FIG. 3, a channel hole 4 is formed in the composite stack structure 3 by etching process, in which the channel hole 4 may open from the upper surface of the composite stack structure 3 and be extended down to a surface of the substrate 1. A cross section contour of the channel hole 4 may be round or polygon.

As shown in FIG. 4, a p-type material layer 5 is formed in the channel hole 4. The material of the p-type material layer 5 may comprise p-type polysilicon.

For example, the doping concentration of the p-type material layer 5 is less than that of the phosphorus silicon glass sacrificial layers 302.

Special needs to be pointed out that, the channel hole 4 may be filled up with the p-type material layer 5, or the p-type material layer 5 may be formed on the side wall and bottom surface of the channel hole 4. In this embodiment, the channel hole 4 is not filled up with the p-type material layer 5, and the p-type material layer 5 constitutes a hollow structure in the channel hole 4. In this situation, the space remaining in the channel hole 4 may be further filled with an insulated material 6. The material of the insulated material 6 may comprise silicon dioxide. In other embodiment, the channel hole 4 is filled up with the p-type material layer 5, and the p-type material layer 5 constitutes a solid column structure in the channel hole 4.

As shown in FIG. 6, a heating treatment is performed to convert a portion of the p-type material layer 5 contacting the phosphorus silicon glass sacrificial layers 302 into n-type doped channel material layers 7, such that the p-type material layers 5 above and below the channel material layers 7 respectively compose the source/drain material layers 5a.

For example, the heating treatment may comprise refluxing the phosphorus silicon glass sacrificial layers 302 at a temperature of 700 to 900° C. for 10 to 60 minutes.

In accordance with the contour of the channel hole 4, the channel material layers 7 present a corresponding annular tube structure. In this embodiment, the channel material layers 7 present an annular tube structure. In other embodiment, when the p-type material layer 5 constitute a solid column structure in the channel hole 4, the p-type material layer 5 at the corresponding portion of the same layer of the phosphorus silicon glass sacrificial layers 302 can be converted into n-type doped channel material layers in the lateral direction by extending the heating time or changing other process parameters, such that the channel material layer presents a plate shape.

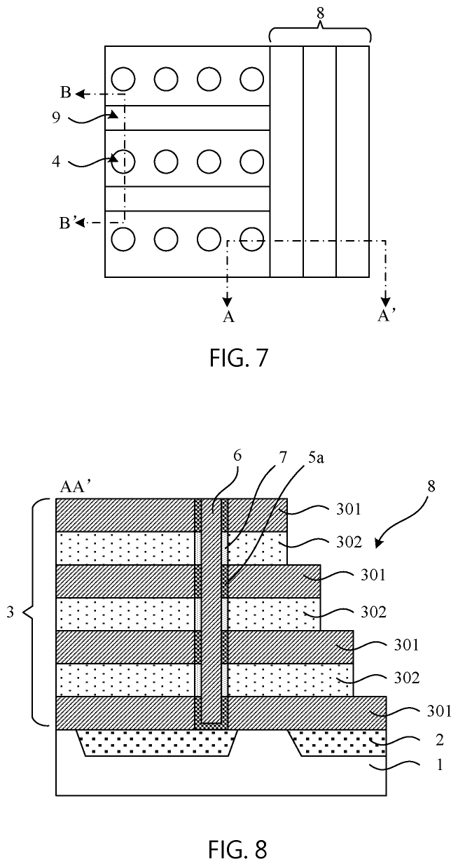

Please refer to FIGS. 7 through 14, a plurality of gate layers 12a staked up in a vertical direction, in which each one of the pluralities of gate layers 12a is connected to one of the channel material layers 7, and the two adjacent gate layers 12a are isolated by one of insulation layers 301.

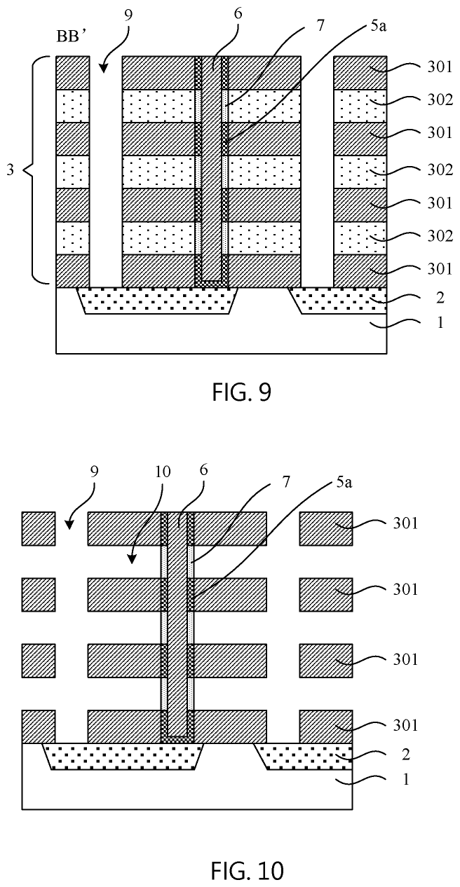

For example, as shown in FIG. 7, the composite stack structure 3 is etched firstly to form a stair-stepped structure 8 on at least one side of the composite stack structure 3, and then a word line cut 9 is formed in the composite stack structure 3, in which FIG. 7 depicts a plant layout diagram of the channel hole 4, the word line cut 9, and the stair-stepped structure 8, FIG. 8 depicts a cross-sectional diagram along taken line AA′ of FIG. 7, and FIG. 9 depicts a cross-sectional diagram along taken line BB′ of FIG. 7.

Specifically, the stair-stepped structure 8 is formed for the convenience of a gate layer stack having a stair-stepped structure subsequently formed, in which a gate layer region exposed on the stair-stepped structure can be used as a pad for extracting each layer of the gate layer. In this embodiment, a stair surface of the stair-stepped structure 8 exposes a partial surface of the insulation layers 301, and the stair-stepped structure 8 may be obtained by etching the pluralities of insulation layers 301 and the pluralities of phosphorus silicon glass sacrificial layers 302 sequentially by using a sequentially decreasing or increasing mask.

Specifically, the word line cut 9 may open from the upper surface of the composite stack structure 3 and be extended down to a surface of the substrate 1, and the word line cut 9 may divide the pluralities of vertical channel structures in groups.

Special needs to be pointed out that, FIG. 0.7 is an example of a plant layout diagram showing the stair-stepped structure on one side of the composite stack structure. In other embodiment, the stair-stepped structure may also be simultaneously formed on opposite sides of the composite stack structure, or simultaneously formed on four sides of the composite stack structure. The word line cut may be extended to the stair-stepped structure and tunnel the stair-stepped structure.

Specifically, the phosphorus silicon glass sacrificial layers 302 may be replaced with conductive layers 12 to form the gate layers 12a. In this embodiment, forming the gate layers 12a comprises the following steps:

As shown in FIG. 10, the phosphorus silicon glass sacrificial layers 302 may be removed firstly to obtain a plurality of lateral gaps 10.

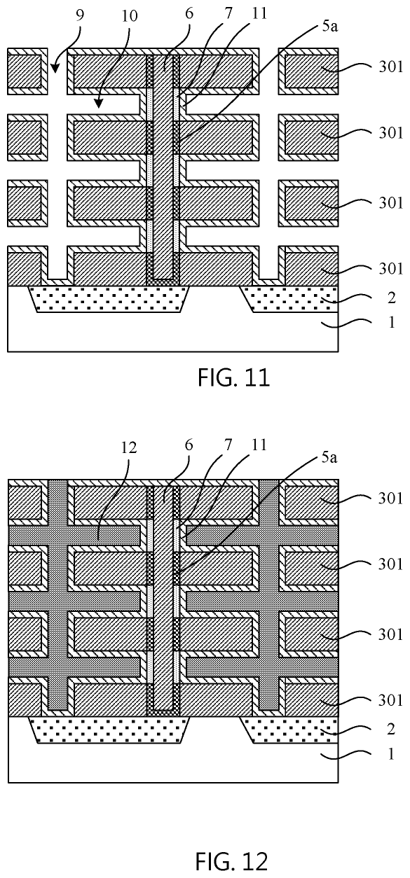

As shown in FIG. 11, a data storage layer 11 may be formed on an external surface of the channel material layers 7. In this embodiment, the data storage layer 11 may further be formed on the surface of the insulation layers 301 exposed by the word line cut 9 and the lateral gaps 10, such that the data storage layer 11 is not only disposed between the channel material layers 7 and the gate layers 12a subsequently formed, but also between the insulation layers 301 and the gate layers 12a subsequently formed. For example, the data storage layer 11 may comprise a tunneling dielectric layer, a charge trap layer and a high-K dielectric layer, in which the tunneling dielectric layer may be connected to the pluralities of channel material layers 7, the high-K dielectric layer may be connected to the pluralities of gate layers 12a, the charge trap layer may be disposed between the tunneling dielectric layer and the high-K dielectric layer, and dielectric constant K of the high-K dielectric layer may be greater than 4. For example, the tunneling dielectric layer may comprise silicon dioxide, t the charge trap layer may comprise silicon nitride, and the high-K dielectric layer may comprise aluminum oxide deposited by atomic layer deposition (ALD) or chemical vapor deposition (CVD).

As shown in FIG. 12, the conductive layers 12 may be formed between the word line cut 9 and the lateral gaps 10 to replace the phosphorus silicon glass sacrificial layers 302. For example, the conductive layers 12 may be tantalum nitride deposited by CVD.

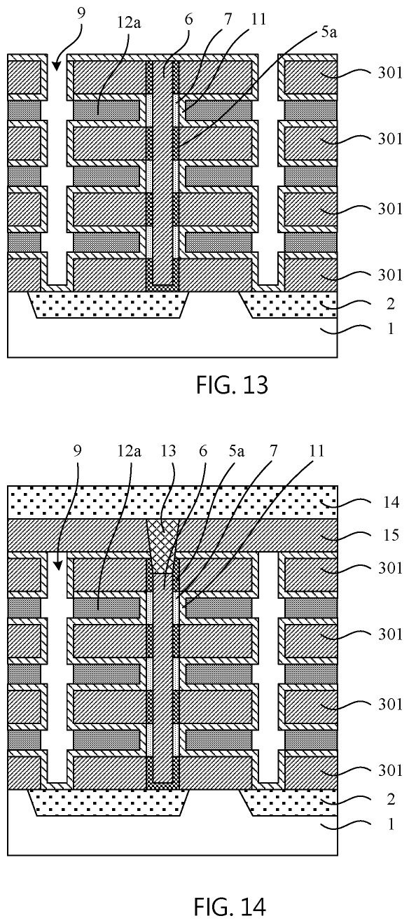

As shown in FIG. 13, a portion of the conductive layers 12 disposed in the word line cut 9 may be removed by dry etching, and the remaining conductive layers 12 nay be disposed in the lateral gaps 10 to constitute the gate layers 12a. Each layer of the gate layers 12a may be as a controlling gate and as a word line. The word line cut 9 may be filled with an insulating medium or not.

Special needs to be pointed out that, the number of layers of the gate layers 12a is not limited to 3 layers as shown in FIG. 13, it may also be other numbers, for example, it can be 8 layers, 16 layers, 32 layers, 64 layers, 128 layers. Each one of vertical channel structures and the pluralities of gate layers surrounded the vertical channel structure constitute a plurality of junction transistors connected in series vertically, which can be applied to 3D NAND string unit structures or other storage structures.

For example, in a string of transistors, the uppermost one and the lowermost one of the transistors may be non-memory units without storage function, and the middle transistors may be memory units with storage function.

For example, an uppermost layer of the gate layers 12a may connected to a secondary uppermost layer of the gate layers 12a by a conductive connector (not shown). In this embodiment, the conductive connector may be disposed on an external side of the stair-stepped structure. An upper end and a lower end of the conductive connector may be connected to a lateral side of the uppermost layer of the gate layers 12a and a lateral side of the secondary uppermost layer of the gate layers 12a respectively. A medium portion of the conductive connector may be connected to a lateral side of the insulation layers 301 between these two gate layers 12a (the uppermost layer and the secondary uppermost layer). Likely, a lowermost layer of the gate layers 12a may connected to a secondary lowermost layer of the gate layers 12a by a conductive connector (not shown). In this embodiment, the conductive connector may be disposed on an external side of the stair-stepped structure. An upper end and a lower end of the conductive connector may be connected to a lateral side of the lowermost layer of the gate layers 12a and a lateral side of the secondary lowermost layer of the gate layers 12a respectively. A medium portion of the conductive connector may be connected to a lateral side of the insulation layers 301 between these two gate layers 12a (the lowermost layer and the secondary lowermost layer).

As shown in FIG. 14, an isolation dielectric layer 15 may be formed on the composite stack structure, a bit line contact 13 may be formed in the isolation dielectric layer 15, and a bit line 14 may be connected above the bit line contact 13. The bit line contact 13 may be extended downward and be connected to the uppermost layer of the source/drain material layers 5a.

The 3D junction semiconductor memory device of this embodiment comprise a plurality of vertical channel structures and a plurality of gate layers staked up in a vertical direction. The pluralities of vertical channel structures comprise multiple alternatively stacked source/drain material layers and channel material layers in a vertical direction, and the source/drain material layers and the channel material layers are doped with different doping types so as to constitute a plurality of junction transistors connected in series vertically, such that not only a smaller component size can be achieved, but also more flexible storage unit operation can be achieved.

### Second Embodiment

This embodiment provide a 3D junction semiconductor memory device. Please refer to FIG. 14, which depicts a cross-sectional diagram of forming a bit line contact and a bit lime in the fabrication method of the 3D junction semiconductor memory device. The 3D junction semiconductor memory device comprise a substrate 1 and a plurality of vertical channel structures and a plurality of gate layers 12a. The pluralities of vertical channel structures may be extended upward on the substrate 1, in which each one of the pluralities of vertical channel structures comprises multiple alternatively stacked source/drain material layers 5a and channel material layers 7 in a vertical direction, an uppermost layer of the vertical channel structures is one of the source/drain material layers 5a, and the source/drain material layers 5a and the channel material layers 7 are doped with different doping types. The pluralities of gate layers 12a may be stacked vertically, each one of the gate layers 12a may be connected to one of the channel material layers 7, and the two adjacent gate layers 12a may be isolated by one of insulation layers 301.

For example, the source/drain material layers 5a and the channel material layers 7 may constitute a hollow structure, and the hollow structure may be filled with an insulated material 6. The channel material layers 7 may have a circular ring structure or a polygon ring structure, and the gate layers 12a may surround the external side of the channel material layers 7.

In other embodiment, the source/drain material layers 5a and the channel material layers 7 may constitute a solid column structure, such as a cylindrical or a polygonal column.

For example, a stair-stepped structure may be formed on at least one side of the gate layers 12a (shown in FIG. 7), and the portion of the gate layers 12a corresponding to the stair-stepped structure can be used as a pad for extracting each layer of the gate layer.

For example, the 3D junction semiconductor memory device may further comprise a word line cut 9, in which the word line cut 9 may tunnel the gate layers 12a and the insulation layers 301. The word line cut 9 may divide the pluralities of vertical channel structures in groups. The word line cut 9 may be filled with an insulating medium or not.

For example, the 3D junction semiconductor memory device may further comprise a data storage layer 11, which may be disposed between the channel material layers 7 and the gate layers 12a. In this embodiment, the data storage layer 1 may be further disposed between the insulation layers 301 and the gate layers 12a. For example, the data storage layer 11 may comprise a tunneling dielectric layer, a charge trap layer and a high-K dielectric layer, in which the tunneling dielectric layer may be connected to the pluralities of channel material layers 7, the high-K dielectric layer may be connected to the pluralities of gate layers 12a, the charge trap layer may be disposed between the tunneling dielectric layer and the high-K dielectric layer, and dielectric constant K of the high-K dielectric layer may be greater than 4. For example, the tunneling dielectric layer may comprise silicon dioxide, t the charge trap layer may comprise silicon nitride, and the high-K dielectric layer may comprise aluminum oxide deposited by atomic layer deposition (ALD) or chemical vapor deposition (CVD).

Special needs to be pointed out that, the number of layers of the gate layers 12a is not limited to 3 layers as shown in FIG. 13, it may also be other numbers, for example, it can be 8 layers, 16 layers, 32 layers, 64 layers, 128 layers. Each one of vertical channel structures and the pluralities of gate layers surrounded the vertical channel structure constitute a plurality of junction transistors connected in series vertically, which can be applied to 3D NAND string unit structures or other storage structures. For example, in a string of transistors, the uppermost one and the lowermost one of the transistors may be non-memory units without storage function, and the middle transistors may be memory units with storage function.

For example, the 3D junction semiconductor memory device may further comprise a conductive connector (not shown), in which an uppermost layer of the gate layers 12a may connected to a secondary uppermost layer of the gate layers 12a by the conductive connector, or a lowermost layer of the gate layers 12a may connected to a secondary lowermost layer of the gate layers 12a by the conductive connector. In this embodiment, the conductive connector may be disposed on an external side of the stair-stepped structure. An upper end and a lower end of the conductive connector may be connected to a lateral side of the uppermost layer of the gate layers 12a and a lateral side of the secondary uppermost layer of the gate layers 12a respectively. A medium portion of the conductive connector may be connected to a lateral side of the insulation layers 301 between these two gate layers 12a. Likely, the conductive connector may be disposed on an external side of the stair-stepped structure. An upper end and a lower end of the conductive connector may be connected to a lateral side of the lowermost layer of the gate layers 12a and a lateral side of the secondary lowermost layer of the gate layers 12a respectively. A medium portion of the conductive connector may be connected to a lateral side of the insulation layers 301 between these two gate layers 12a.

For example, the 3D junction semiconductor memory device may further comprise a bit line contact 13 and a bit line 14, in which the bit line contact 13 may be formed in the isolation dielectric layer 15 and connected to an uppermost layer of the source/drain material layers 5a, and the bit line 14 may be connected above the bit line contact 13.

The 3D junction semiconductor memory device of this embodiment comprise a plurality of vertical channel structures and a plurality of gate layers staked up in a vertical direction. The pluralities of vertical channel structures comprise multiple alternatively stacked source/drain material layers and channel material layers in a vertical direction, and the source/drain material layers and the channel material layers are doped with different doping types so as to constitute a plurality of junction transistors connected in series vertically, such that not only a smaller component size can be achieved, but also more flexible storage unit operation can be achieved.

Above all, the 3D junction semiconductor memory device of the present invention comprise a plurality of vertical channel structures and a plurality of gate layers staked up in a vertical direction. The pluralities of vertical channel structures comprise multiple alternatively stacked source/drain material layers and channel material layers in a vertical direction, and the source/drain material layers and the channel material layers are doped with different doping types so as to constitute a plurality of junction transistors connected in series vertically, such that not only a smaller component size can be achieved, but also more flexible storage unit operation can be achieved. The fabrication method of 3D junction semiconductor memory device of the present invention is capably of subtly forming multiple alternatively stacked source/drain material layers and the channel material layers, so as to realize the 3D junction semiconductor memory device which is difficult to be obtained by ion implantation technology. Therefore, the present invention effectively overcomes various shortcomings in the prior art and has high industrial utilization value.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A fabrication method of a three-dimensional (3D) junction semiconductor memory device, comprising steps of:
providing a substrate;
forming a plurality of vertical channel structures extended upward on the substrate, wherein each one of the pluralities of vertical channel structures comprises multiple alternatively stacked source/drain material layers and channel material layers in a vertical direction, an uppermost layer of the vertical channel structures is one of the source/drain material layers, and the source/drain material layers and the channel material layers are doped with different doping types; and
forming a plurality of gate layers staked up in a vertical direction, wherein each one of the pluralities of gate layers is connected to one of the channel material layers, and the two adjacent gate layers are isolated by one of insulation layers.

2. The fabrication method according to claim 1, wherein the step of forming a plurality of vertical channel structures comprises:
forming a composite stack structure on the substrate, wherein the composite stack structure comprises multiple alternatively stacked insulation layers and phosphorus silicon glass sacrificial layers, wherein an uppermost layer of the composite stack structure is one of the insulation layers;
forming a channel hole in the composite stack structure, wherein the channel hole opens from the upper surface of the composite stack structure and extends down to a surface of the substrate;
forming a p-type material layer in the channel hole; and
performing a heating treatment to convert a portion of the p-type material layer contacting the phosphorus silicon glass sacrificial layers into n-type doped channel material layers, such that the p-type material layers above and below the channel material layers respectively compose the source/drain material layers.

3. The fabrication method according to claim 2, wherein the channel hole is not filled up with the p-type material layer, the p-type material layer constitutes a hollow structure in the channel hole, and the fabrication method further comprises a step of filling the space remaining in the channel hole with an insulated material.

4. The fabrication method according to claim 2, wherein the channel hole is filled up with the p-type material layer, and the p-type material layer constitutes a solid column structure in the channel hole.

5. The fabrication method according to claim 2, further comprising a step of etching the composite stack structure to form a stair-stepped structure on at least one side of the composite stack structure.

6. The fabrication method according to claim 5, wherein a stair surface of the stair-stepped structure exposes a partial surface of the insulation layers.

7. The fabrication method according to claim 5, wherein the stair-stepped structure is obtained by a step of etching the pluralities of insulation layers and the pluralities of phosphorus silicon glass sacrificial layers sequentially by using a sequentially decreasing or increasing mask.

8. The fabrication method according to claim 2, further comprising a step of forming a word line cut in the composite stack structure, wherein the word line cut opens from the upper surface of the composite stack structure and extends down to a surface of the substrate, and the word line cut divides the pluralities of vertical channel structures in groups.

9. The fabrication method according to claim 2, further comprising a step of replacing the phosphorus silicon glass sacrificial layers with conductive layers to form the gate layers.

10. The fabrication method according to claim 1, further comprising a step of forming a data storage layer, wherein the data storage layer is disposed between the pluralities of channel material layers and the pluralities of gate layers.

11. The fabrication method according to claim 10, wherein the data storage layer is disposed between the pluralities of insulation layers and the pluralities of gate layers.

12. The fabrication method according to claim 10, wherein the data storage layer comprises a tunneling dielectric layer, a charge trap layer and a high-K dielectric layer, the tunneling dielectric layer is connected to the pluralities of channel material layers, the high-K dielectric layer is connected to the pluralities of gate layers, the charge trap layer is disposed between the tunneling dielectric layer and the high-K dielectric layer, and dielectric constant K of the high-K dielectric layer is greater than 4.

13. The fabrication method according to claim 10, further comprising a step of forming a bit line contact and a bit line, the bit line contact is connected to an uppermost layer of the source/drain material layers, and the bit line is connected above the bit line contact.

14. The fabrication method according to claim 1, wherein an uppermost layer of the gate layers is connected to a secondary uppermost layer of the gate layers by a conductive connector.

15. The fabrication method according to claim 1, wherein a lowermost layer of the gate layers is connected to a secondary lowermost layer of the gate layers by a conductive connector.

16. A 3D junction semiconductor memory device, comprising:
a substrate;
a plurality of vertical channel structures, extended upward on the substrate, wherein each one of the pluralities of vertical channel structures comprises multiple alternatively stacked source/drain material layers and channel material layers in a vertical direction, an uppermost layer of the vertical channel structures is one of the source/drain material layers, and the source/drain material layers and the channel material layers are doped with different doping types; and
a plurality of gate layers, staked up in a vertical direction, wherein each one of the pluralities of gate layers is connected to one of the channel material layers, and the two adjacent gate layers are isolated by one of insulation layers.

17. The device according to claim 16, wherein the source/drain material layers and the channel material layers constitute a hollow structure, and the hollow structure is filled with an insulated material.

18. The device according to claim 16, wherein the source/drain material layers and the channel material layers constitute a solid column structure.

19. The device according to claim 16, wherein a stair-stepped structure is formed on at least one side of the pluralities of gate layers.

20. The device according to claim 16, further comprising a word line cut, wherein the word line cut tunnels the pluralities of gate layers and the insulation layers, and the word line cut divides the pluralities of vertical channel structures in groups.

21. The device according to claim 16, further comprising a data storage layer, wherein the data storage layer is disposed between the pluralities of channel material layers and the pluralities of gate layers.

22. The device according to claim 21, wherein the data storage layer is disposed between the pluralities insulation layers and the pluralities of gate layers.

23. The device according to claim 16, further comprising a bit line contact and a bit line, wherein the bit line contact is connected to an uppermost layer of the source/drain material layers, and the bit line is connected above the bit line contact.

24. The device according to claim 16, further comprising a conductive connector is connected between an uppermost layer of the gate layers and a secondary uppermost layer of the gate layers, and connected between an lowermost layer of the gate layers and a secondary lowermost layer of the gate layers.
